(19) United States
(12) Patent Application Publication
(10) Pub. No.: US 2021/0408062 A1
(43) Pub. Date: Dec. 30, 2021

(54) TFT ARRAY SUBSTRATE AND MANUFACTURING METHOD THEREOF

(71) Applicant: TCL CHINA STAR OPTOELECTRONICS TECHNOLOGY CO., LTD., Shenzhen (CN)

(72) Inventor: Fen LONG, Shenzhen (CN)

(73) Assignee: TCL CHINA STAR OPTOELECTRONICS TECHNOLOGY CO., LTD., Shenzhen (CN)

(21) Appl. No.: 16/757,400

(22) PCT Filed: Jan. 7, 2020
(86) PCT No.: PCT/CN2020/070570

§ 371 Date: Apr. 19, 2020

(30) Foreign Application Priority Data
Dec. 26, 2019 (CN) 201911362574.2

(51) Int. Cl. H01L 27/12; H01L 29/786

(52) U.S. Cl. CPC H01L 27/127; H01L 29/78669

(57) ABSTRACT

The present invention provides a thin-film transistor (TFT) array substrate and a manufacturing method thereof. The manufacturing method uses a four-mask process that uses an etch-stop layer on a semiconductor layer as a mask to perform alignment and etching to form a pattern of an amorphous silicon island. Tail fibers exposed outside of a source and a drain are removed, photoelectric sensitivity of a TFT device can be effectively reduced, and size of the TFT device is reduced, which can simplify processes, save layout space, and effectively increase display quality of large-size and high-resolution liquid crystal panels under high backlight intensity.

### FIELD OF INVENTION

The present invention is related to the display field, and specifically to a thin-film transistor (TFT) array substrate and a manufacturing method thereof.

### BACKGROUND OF INVENTION

With the development of large-size and high-resolution liquid crystal display panels, in order to increase display quality of high-end products, luminous intensity of backlight of liquid crystal display panels is increased, pixel size is decreased, and thin-film transistor (TFT) devices of the liquid crystal display panels accordingly require a higher standard.

The TFT devices are multilayer thin-film structures formed by multiple exposure, development, and etching processes. In a traditional process, a TFT device need to be formed by a four-mask process. In a traditional four-mask process, an amorphous silicon island, a source, and a drain need to be formed by a one-mask process for exposure and development, two wet etchings, and two dry etchings. Due to a difference between wet etching characteristics and dry etching characteristics of metals, tail fibers of a certain length exist in a semiconductor layer under the source and the drain. However, since the semiconductor layer is usually made of a photosensitive material, during an application of a display panel, when refracted light or reflected light irradiates on a part of the exposed semiconductor layer of the TFT device, a leakage current of the TFT device is easily increased, which makes a holding ability of a pixel voltage weak and affects display quality of the display panel.

In summary, it is necessary to provide a new TFT array substrate and a manufacturing method thereof to solve the above technical problems.

### SUMMARY OF INVENTION

A thin-film transistor (TFT) and a manufacturing method thereof provided by the present invention solve technical problems that a prior TFT has tail fibers of a certain length existing in a semiconductor layer under a source and a drain, which easily leads a leakage current of the TFT device to increase when refracted light or reflected light irradiates on a part of the exposed semiconductor layer of the TFT device, and makes a holding ability of a pixel voltage weak and affects display quality of a display panel.

In order to solve the above problems, the present invention provides technical solution as follows.

The present invention provides the manufacturing method of the TFT array substrate, including the steps of:

S10: providing a base substrate, forming a first metal layer on the base substrate, patterning the first metal layer with a first mask process to form a gate, and sequentially forming a gate insulating layer, a semiconductor layer, an etch-stop layer, and a second metal layer, wherein material of the gate insulating layer includes silicon oxide or silicon nitride;

S20: patterning the second metal layer, the etch-stop layer, and the semiconductor layer with a second mask process to form a source, a drain, and an amorphous silicon island, wherein an edge of the amorphous silicon island is aligned with an edge of the source, an edge of the drain, and an edge of the etch-stop layer;

S30: forming a passivation layer on the gate insulating layer, the source, and the drain, and patterning the passivation layer with a third mask process to form a through-hole; and

S40: patterning a pixel electrode on the passivation layer with a fourth mask process, wherein the pixel electrode is connected to the drain by the through-hole.

According to the manufacturing method of the TFT array substrate provided by an embodiment of the present invention, the step S20 further includes the steps of:

S201: coating a photoresist material on the second metal layer;

S202: exposing and developing the photoresist material with the second mask to form a first photoresist layer;

S203: etching and removing the second metal layer and the etch-stop layer not covered by the first photoresist layer;

S204: ashing the first photoresist layer to form a second photoresist layer, wherein the second photoresist layer corresponds to the source and the drain;

S205: etching the second metal layer to form the source and the drain;

S206: striping the second photoresist layer; and

S207: etching and removing the semiconductor layer not covered by the etch-stop layer, the source, and the drain.

According to the manufacturing method of the TFT array substrate provided by an embodiment of the present invention, the semiconductor layer includes an amorphous silicon layer and a N+ amorphous silicon layer. The step S207 further includes etching and removing the N+ amorphous silicon layer of a channel region to expose the amorphous silicon layer.

According to the manufacturing method of the TFT array substrate provided by an embodiment of the present invention, the step S207 further includes the steps of:

S2071: removing the semiconductor layer outside the etch-stop layer by a dry etching process using the etch-stop layer as a mask;

S2072: removing the etch-stop layer of the channel region by the dry etching process using the source and the drain as a mask; and

S2073: removing the N+ amorphous silicon layer of the channel region to expose the amorphous silicon layer by the dry etching process using the etch-stop layer as a mask.

According to the manufacturing method of the TFT array substrate provided by an embodiment of the present invention, a thickness of removing the N+ amorphous silicon layer of the channel region ranges from 100 to 500 angstroms (Å).

According to the manufacturing method of the TFT array substrate provided by an embodiment of the present invention, the step S2071, the step S2072, and the step S2073 use a same dry etching process.

According to the manufacturing method of the TFT array substrate provided by an embodiment of the present invention, a length of removing the semiconductor layer outside the etch-stop layer ranges from one to two micrometers.

According to the manufacturing method of the TFT array substrate provided by an embodiment of the present invention, the step S203 uses a wet etching process, and the step S205 uses the wet etching process.

According to the manufacturing method of the TFT array substrate provided by an embodiment of the present invention, the second mask includes a halftone mask.

An embodiment of the present invention provides a thin-film transistor (TFT) array substrate, including the steps of:

S10: providing a base substrate, forming a first metal layer on the base substrate, patterning the first metal layer with a first mask process to form a gate, and sequentially forming a gate insulating layer, a semiconductor layer, an etch-stop layer, and a second metal layer;

S20: patterning the second metal layer, the etch-stop layer, and the semiconductor layer with a second mask process to form a source, a drain, and an amorphous silicon island, wherein an edge of the amorphous silicon island is aligned with an edge of the source, an edge of the drain, and an edge of the etch-stop layer;

S30: forming a passivation layer on the gate insulating layer, the source, and the drain, and patterning the passivation layer with a third mask process to form a through-hole; and

S40: patterning a pixel electrode on the passivation layer with a fourth mask process, wherein the pixel electrode is connected to the drain by the through-hole.

According to the manufacturing method of the TFT array substrate provided by an embodiment of the present invention, the step S20 further includes the steps of:

S201: coating a photoresist material on the second metal layer;

S202: exposing and developing the photoresist material with the second mask to form a first photoresist layer;

S203: etching and removing the second metal layer and the etch-stop layer not covered by the first photoresist layer;

S204: ashing the first photoresist layer to form a second photoresist layer, wherein the second photoresist layer corresponds to the source and the drain;

S205: etching the second metal layer to form the source and the drain;

S206: striping the second photoresist layer; and

S207: etching and removing the semiconductor layer not covered by the etch-stop layer, the source, and the drain.

According to the manufacturing method of the TFT array substrate provided by an embodiment of the present invention, the semiconductor layer includes an amorphous silicon layer and a N+ amorphous silicon layer. The step S207 further includes etching and removing the N+ amorphous silicon layer of a channel region to expose the amorphous silicon layer.

According to the manufacturing method of the TFT array substrate provided by an embodiment of the present invention, the step S207 further includes the steps of:

S2071: removing the semiconductor layer outside the etch-stop layer by a dry etching process using the etch-stop layer as a mask;

S2072: removing the etch-stop layer of the channel region by the dry etching process using the source and the drain as a mask; and

S2073: removing the N+ amorphous silicon layer of the channel region to expose the amorphous silicon layer by the dry etching process using the etch-stop layer as a mask.

According to the manufacturing method of the TFT array substrate provided by an embodiment of the present invention, a thickness of removing the N+ amorphous silicon layer of the channel region ranges from 100 to 500 angstroms (Å).

According to the manufacturing method of the TFT array substrate provided by an embodiment of the present invention, the step S2071, the step S2072, and the step S2073 use a same dry etching process.

According to the manufacturing method of the TFT array substrate provided by an embodiment of the present invention, the step S203 uses a wet etching process, and the step S205 uses the wet etching process.

According to the manufacturing method of the TFT array substrate provided by an embodiment of the present invention, the second mask includes a halftone mask.

An embodiment of the present invention provides a thin-film transistor (TFT) array substrate, including:

a base substrate;

a gate disposed on the base substrate;

a gate insulating layer covering the gate and the base substrate;

an amorphous silicon island disposed on the gate insulating layer;

an etch-stop layer disposed on the amorphous silicon island;

a source and a drain disposed on the etch-stop layer, and a channel region formed between the source and the drain;

a passivation layer disposed on the gate insulating layer, the source, and the drain, and a through-hole disposed on the passivation layer;

and

a pixel electrode disposed on the passivation layer, wherein the pixel electrode is connected to the drain by the through-hole;

wherein an edge of the amorphous silicon island is aligned with an edge of the source, an edge of the drain, and an edge of the etch-stop layer.

According to the TFT array substrate provided by an embodiment of the present invention, the amorphous silicon island includes an amorphous silicon layer and a N+ amorphous silicon layer, the N+ amorphous silicon layer corresponds to the source and the drain, and the amorphous silicon layer corresponds to the source, the drain, and the channel region.

Beneficial effects of the present invention: the TFT array substrate and the manufacturing method thereof provided by the present invention uses a four-mask process that uses the etch-stop layer on the semiconductor layer as a mask to perform alignment and etching to form a pattern of the amorphous silicon island. The tail fibers exposed outside of the source and the drain are removed, so that the edge of the amorphous silicon island is aligned with the edge of the source, the edge of the drain, and the edge of the etch-stop layer. Therefore, photoelectric sensitivity of the TFT device can be effectively reduced, and an area of the amorphous silicon island is reduced, thereby reducing size of the TFT device, which is beneficial to saving layout. At the same time, processes can be simplified and layout space can be saved, which means that display quality of large-size and high-resolution liquid crystal panels under high backlight intensity can be effectively increased.

### DESCRIPTION OF DRAWINGS

In order to describe embodiments and technical solutions in the prior art clearly, drawings to be used in the description of the embodiments or the prior art will be described briefly below. Obviously, drawings described below are only for some embodiments of the present invention, and other drawings may be obtained by those skilled in the art based on these drawings without creative efforts.

FIG. 1 is a flowchart of a manufacturing method of a thin-film transistor (TFT) array substrate provided by an embodiment of the present invention.

FIG. 2 is a flowchart of step S20 in the manufacturing method of the TFT array substrate provided by an embodiment of the present invention.

FIG. 3 is a flowchart of step S207 in the manufacturing method of the TFT array substrate provided by an embodiment of the present invention.

FIGS. 4A to 4M are structural diagrams of processes of the manufacturing method of the TFT array substrate provided by an embodiment of the present invention.

FIG. 5 is a cross-sectional diagram of the TFT array substrate provided by an embodiment of the present invention.

### DETAILED DESCRIPTION OF PREFERRED EMBODIMENTS

Examples are described below with reference to the appended drawings, and the drawings illustrate particular embodiments in which the present invention may be practiced. Directional terms mentioned in the present invention, such as upper, lower, front, rear, left, right, in, out, side, etc., only refer to directions in the accompanying drawings. Thus, the adoption of directional terms is used to describe and understand the present invention, but not to limit the present invention. In the drawings, units of similar structures are represented using the same numerals.

The present invention can solve defects of a thin-film transistor (TFT) array substrate and a manufacturing method thereof of the prior art. Because tail fibers of a certain length exist in a semiconductor layer under a source and a drain, which easily leads a leakage current of a TFT device to increase when refracted light or reflected light irradiates on a part of the exposed semiconductor layer of the TFT device, and makes a holding ability of a pixel voltage weak and affects display quality of a display panel.

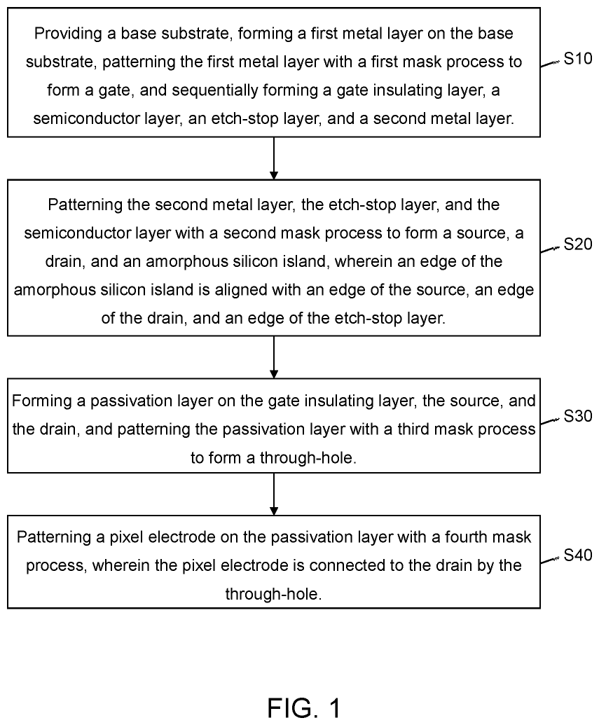

As shown in FIG. 1, a manufacturing method of a TFT array substrate provided by an embodiment of the present invention takes a four-mask process as an example. The manufacturing method includes the steps of:

S10: providing a base substrate 10, forming a first metal layer 20 on the base substrate 10, patterning the first metal layer 20 with a first mask process to form a gate 201, and sequentially forming a gate insulating layer 30, a semiconductor layer 40, an etch-stop layer 50, and a second metal layer 60.

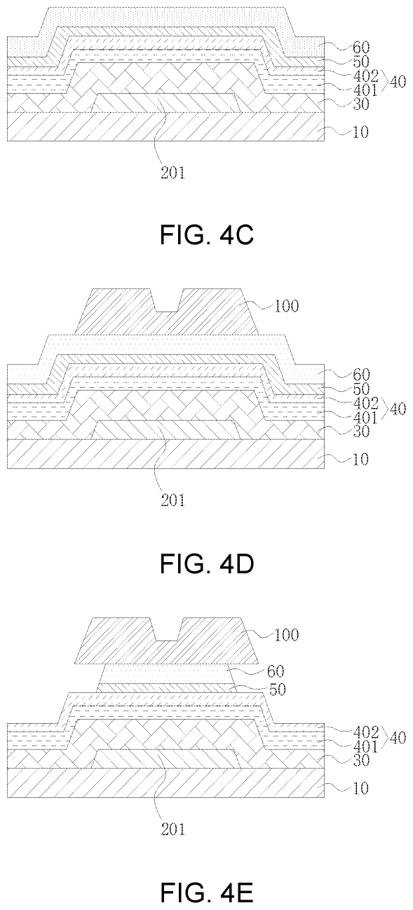

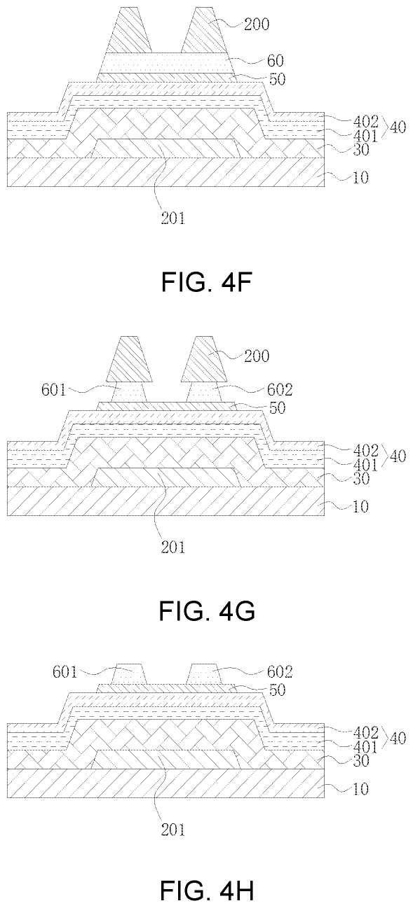

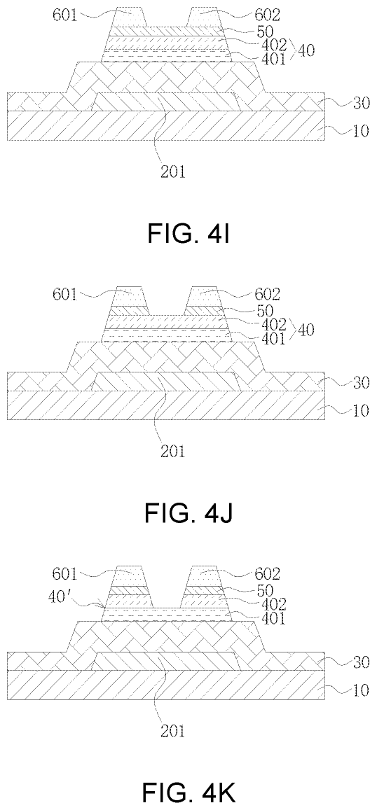

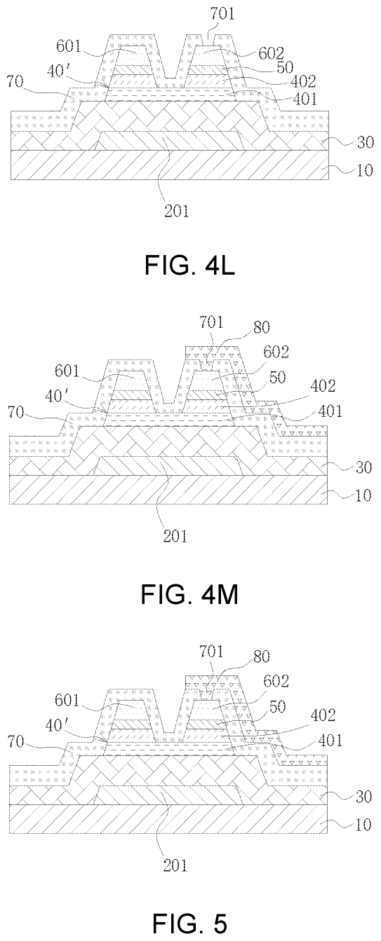

Specifically, as shown in FIG. 4A, the first metal layer 20 can be deposited by a physical vapor deposition process. Material of the first metal layer 20 can be copper, aluminum, or molybdenum. As shown in FIG. 4B, the first metal layer 20 is exposed, developed, and etched by the first mask process to form the gate 201 on the base substrate 10.

After that, as shown in FIG. 4C, the gate insulating layer 30 is deposited on the gate 201 and the base substrate 10. The semiconductor layer 40 is deposited on the gate insulating layer 30. The etch-stop layer 50 is deposited on the semiconductor layer 40. The second metal layer 60 is deposited on the etch-stop layer 50. Material of the gate insulating layer 30 can be silicon oxide or silicon nitride. Material of the etch-stop layer 50 is metal. The semiconductor layer 40 includes an amorphous silicon layer 401 and a N+ amorphous silicon layer 402 which are stacked. The amorphous silicon layer 401 is formed on the gate insulating layer 30. The N+ amorphous silicon layer 402 is formed on the amorphous silicon layer 401.

S20: patterning the second metal layer 60, the etch-stop layer 50, and the semiconductor layer 40 with a second mask process to form a source 601, a drain 602, and an amorphous silicon island 40′, wherein an edge of the amorphous silicon island 40′ is aligned with an edge of the source 601, an edge of the drain 602, and an edge of the etch-stop layer 50.

It needs to be explained that patterning the semiconductor layer 40 to form the amorphous silicon island 40′ includes patterning both the amorphous silicon layer 401 and the N+ amorphous silicon layer 402 to remove a tail fiber of the amorphous silicon layer 401 and a tail fiber of the N+ amorphous silicon layer 402.

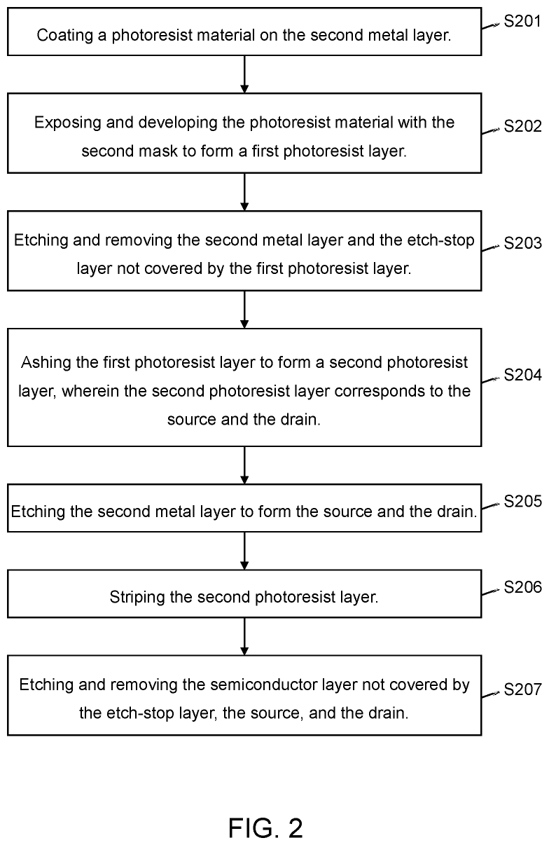

Specifically, as shown in FIG. 2, the step S20 further includes the steps of:

S201: coating a photoresist material on the second metal layer 60.

S202: exposing and developing the photoresist material with the second mask to form a first photoresist layer 100.

As shown in FIG. 4D, the photoresist material is exposed and developed by a halftone mask to remove a part of the photoresist material located on edges of two sides and corresponding to a channel region 603. The photoresist material which is remained becomes the first photoresist layer 100. A thickness of the first photoresist layer 100 corresponding to the channel region 603 is less than a thickness of the first photoresist layer 100 corresponding to other regions.

S203: etching and removing the second metal layer 60 and the etch-stop layer 50 not covered by the first photoresist layer 100.

Specifically, as shown in FIG. 4E, the wet etching process can be adopted. Because the wet etching process is isotropic, after the wet etching process, an orthographic projection of the second metal layer 60 and the etch-stop layer 50 on the base substrate 10 is located in an orthographic projection of the first photoresist layer 100 on base substrate 10. That is, at least the second metal layer 60 and the etch-stop layer 50 which are not covered by the first photoresist layer 100 are removed.

S204: ashing the first photoresist layer 100 to form a second photoresist layer 200, wherein the second photoresist layer 200 corresponds to the source 601 and the drain 602.

Specifically, as shown in FIG. 4F, the photoresist material corresponding to the channel region 603 is removed. The photoresist material which is remained becomes the second photoresist layer 200. The second photoresist layer 200 corresponds to the source 601 and the drain 602 which are subsequently formed.

S205: etching the second metal layer 60 to form the source 601 and the drain 602.

Similarly, as shown in FIG. 4G, the second metal layer 60 corresponding to the channel region 603 can be removed by the wet etching process. The second metal layer 60 which is remained becomes the source 601 and the drain 602.

S206: striping the second photoresist layer 200.

As shown in FIG. 4H, the second photoresist layer 200 is striped from the source 601 and the drain 602.

S207: etching and removing the semiconductor layer 40 not covered by the etch-stop layer 50, the source 601, and the drain 602.

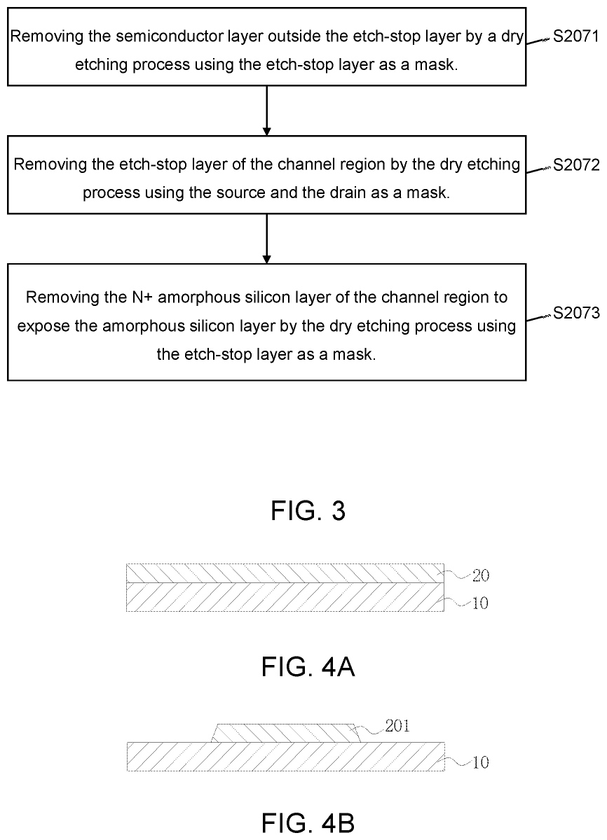

Specifically, as shown in FIG. 3, the step S207 further includes the steps of:

S2071: removing the semiconductor layer 40 outside the etch-stop layer 50 by a dry etching process using the etch-stop layer 50 as a mask.

Specifically, as shown in FIG. 4I, the amorphous silicon layer 401 and the N+ amorphous silicon layer 402 outside the etch-stop layer 50 is removed by the dry etching process. Using the etch-stop layer 50 as the mask and without consideration of alignment space between the etch-stop layer 50 and the semiconductor layer 40, an edge of the amorphous silicon layer 401 and an edge of the N+ amorphous silicon layer 402 can be aligned with the edge of the source 601, the edge of the drain 602, and the edge of the etch-stop layer 50. As a result, the tail fiber of the amorphous silicon layer and the tail fiber of the N+ amorphous silicon layer which are exposed outside the source 601 and the edge of the drain 602 can be completely removed, and the leakage current of the TFT device is prevented from increasing when refracted light or reflected light irradiates on the part of the exposed semiconductor layer 40 of the TFT device, which can increase light stability of the TFT device.

Compared to a conventional process, in this embodiment of the present invention, a length of removing the semiconductor layer outside the etch-stop layer ranges from one to two micrometers.

Understandably, the etch-stop layer 50 remains in the channel region 603, which can protect the semiconductor layer 40 in the channel region 603 from being affected by the etching.

S2072: removing the etch-stop layer 50 of the channel region 603 by the dry etching process using the source 601 and the drain 602 as a mask.

Similarly, as shown in FIG. 4J, the etch-stop layer 50 of the channel region 603 is removed by the dry etching process, continuously, so that the N+ amorphous silicon layer of the channel region 603 can be etched subsequently.

S2073: removing the N+ amorphous silicon layer 402 of the channel region 603 to expose the amorphous silicon layer 401 by the dry etching process using the etch-stop layer 50 as a mask.

Similarly, as shown in FIG. 4K, the N+ amorphous silicon layer 402 of the channel region 603 is removed to expose the amorphous silicon layer 401 by the dry etching process, continuously. The tail fiber of the N+ amorphous silicon layer in the channel region 603 can be completely removed to form the TFT device. Because a structure without the tail fiber of the N+ amorphous silicon layer can reduce a metal area of the source 601 and drain 602, size of the TFT device can be reduced, which is beneficial to saving layout.

It needs to be explained that the steps S2071, S2072, and S2073 use continuous dry etching processes, which can be regarded as a same dry etching process.

S30: forming a passivation layer 70 on the gate insulating layer 30, the source 601, and the drain 602, and patterning the passivation layer 70 with a third mask process to form a through-hole 701.

Specifically, as shown in FIG. 4L, the passivation layer can be deposited by a physical vapor deposition process. Material of the passivation layer 70 can be an oxide, a nitride, or an oxygen-nitrogen compound. The passivation layer 70 is exposed, developed, and etched by the third mask process to form the through-hole 701.

S40: patterning a pixel electrode 80 on the passivation layer with a fourth mask process, wherein the pixel electrode 80 is connected to the drain 602 by the through-hole 701.

Specifically, as shown in FIG. 4M, after the through-hole 701 is formed, a transparent conductive layer can be formed by sputtering or thermal evaporation. Then the transparent conductive layer is exposed, developed, and etched by a fifth mask process to form the pixel electrode 80. The pixel electrode 80 is connected to the drain 602 by the through-hole 701.

Understandably, comparing the TFT array substrate formed by the manufacturing method provided by this embodiment of the present invention to a traditional four-mask process, a length of the amorphous silicon layer exposed outside the source 601 and the drain 602 is only a distance that the source 601 and the drain 602 retreat to the second photoresist layer 200 after the wet etching process in the S205. The wet etching process in that step only etches the source 601 and the drain 602, which has a less retreat distance, so an area of the amorphous silicon island 40′ can be effectively reduced, and the size of the TFT device can be reduced, which effectively increases display quality of large-size and high-resolution liquid crystal panels under high backlight intensity.

As shown in FIG. 5, the TFT array substrate provided by an embodiment of the present invention includes the base substrate 10, the gate 201, the gate insulating layer 30, the amorphous silicon island 40′, the etch-stop layer 50, the source 601, the drain 602, the passivation layer 70, and the pixel electrode 80. The gate 201 is disposed on the base substrate 10. The gate insulating layer 30 covers the gate 201 and the base substrate 10. The amorphous silicon island 40′ is disposed on the gate insulating layer 30. The etch-stop layer 50 is disposed on the amorphous silicon island 40′. The source 601 and the drain 602 is disposed on the etch-stop layer 50. The channel region 603 is formed between the source 601 and the drain 602. The passivation layer 70 is disposed on the gate insulating layer 30, the source 601, and the drain 602. The through-hole 701 is disposed on the passivation layer 70. The pixel electrode 80 is disposed on the passivation layer 70, and the pixel electrode 80 is connected to the drain 602 by the through-hole 701.

The edge of the amorphous silicon island 40′ is aligned with the edge of the source 601, the edge of the drain 602, and the edge of the etch-stop layer 50.

The amorphous silicon island 40′ includes the amorphous silicon layer 401 and the N+ amorphous silicon layer 402. The amorphous silicon layer 401 corresponds to the source 601, the drain 602, and the channel region 603. The amorphous silicon layer 401 is disposed on the base substrate 10. The N+ amorphous silicon layer 402 is disposed on the amorphous silicon layer 401. The gate insulating layer 30 corresponding to an outer side of the source 601 and an outer side of the drain 602 does not have the tail fiber of the amorphous silicon layer and the tail fiber of the N+ amorphous silicon layer. The amorphous silicon layer 401 corresponding to the channel region 603 does not have the tail fiber of the N+ amorphous silicon layer. Therefore, the leakage current of the TFT device is prevented from increasing when refracted light or reflected light irradiates on the part of the exposed semiconductor layer 40 of the TFT device, which can increase light stability of the TFT device. At the same time, the area of the amorphous silicon island 40′ can be effectively reduced, and the size of the TFT device can be reduced, which is beneficial to saving layout.

Beneficial effects: the TFT array substrate and the manufacturing method thereof provided by the present invention uses the four-mask process that uses the etch-stop layer on the semiconductor layer as the mask to perform alignment and etching to form a pattern of the amorphous silicon island. The tail fibers exposed outside of the source and the drain are removed, so that the edge of the amorphous silicon island is aligned with the edge of the source, the edge of the drain, and the edge of the etch-stop layer. Therefore, photoelectric sensitivity of the TFT device can be effectively reduced, and the area of the amorphous silicon island is reduced, thereby reducing the size of the TFT device, which is beneficial to saving layout. At the same time, processes can be simplified and layout space can be saved, which means that display quality of large-size and high-resolution liquid crystal panels under high backlight intensity can be effectively increased.

The foregoing are only preferred embodiments and are not for use in limiting the present invention. Any modification, equivalent replacement, or improvement made without departing from the spirit and principles shall be covered by the protection scope.

What is claimed is:

1. A manufacturing method of a thin-film transistor (TFT) array substrate, comprising the steps of:
S10: providing a base substrate, forming a first metal layer on the base substrate, patterning the first metal layer with a first mask process to form a gate, and sequentially forming a gate insulating layer, a semiconductor layer, an etch-stop layer, and a second metal layer, wherein material of the gate insulating layer comprises silicon oxide or silicon nitride;
S20: patterning the second metal layer, the etch-stop layer, and the semiconductor layer with a second mask process to form a source, a drain, and an amorphous silicon island, wherein an edge of the amorphous silicon island is aligned with an edge of the source, an edge of the drain, and an edge of the etch-stop layer;
S30: forming a passivation layer on the gate insulating layer, the source, and the drain, and patterning the passivation layer with a third mask process to form a through-hole; and
S40: patterning a pixel electrode on the passivation layer with a fourth mask process, wherein the pixel electrode is connected to the drain by the through-hole.

2. The manufacturing method of the TFT array substrate according to claim 1, wherein the step S20 further comprises the steps of:
S201: coating a photoresist material on the second metal layer;
S202: exposing and developing the photoresist material with the second mask to form a first photoresist layer;
S203: etching and removing the second metal layer and the etch-stop layer not covered by the first photoresist layer;
S204: ashing the first photoresist layer to form a second photoresist layer, wherein the second photoresist layer corresponds to the source and the drain;
S205: etching the second metal layer to form the source and the drain;
S206: striping the second photoresist layer; and
S207: etching and removing the semiconductor layer not covered by the etch-stop layer, the source, and the drain.

3. The manufacturing method of the TFT array substrate according to claim 2, wherein the semiconductor layer comprises an amorphous silicon layer and a N+ amorphous silicon layer; and
the step S207 further comprises etching and removing the N+ amorphous silicon layer of a channel region to expose the amorphous silicon layer.

4. The manufacturing method of the TFT array substrate according to claim 3, wherein the step S207 further comprises the steps of:
S2071: removing the semiconductor layer outside the etch-stop layer by a dry etching process using the etch-stop layer as a mask;
S2072: removing the etch-stop layer of the channel region by the dry etching process using the source and the drain as a mask; and
S2073: removing the N+ amorphous silicon layer of the channel region to expose the amorphous silicon layer by the dry etching process using the etch-stop layer as a mask.

5. The manufacturing method of the TFT array substrate according to claim 4, wherein a thickness of removing the N+ amorphous silicon layer of the channel region ranges from 100 to 500 angstroms (Å).

6. The manufacturing method of the TFT array substrate according to claim 4, wherein the step S2071, the step S2072, and the step S2073 use a same dry etching process.

7. The manufacturing method of the TFT array substrate according to claim 4, wherein a length of removing the semiconductor layer outside the etch-stop layer ranges from one to two micrometers.

8. The manufacturing method of the TFT array substrate according to claim 2, wherein the step S203 uses a wet etching process, and the step S205 uses the wet etching process.

9. The manufacturing method of the TFT array substrate according to claim 1, wherein the second mask comprises a halftone mask.

10. A manufacturing method of a thin-film transistor (TFT) array substrate, comprising the steps of:
S10: providing a base substrate, forming a first metal layer on the base substrate, patterning the first metal layer with a first mask process to form a gate, and sequentially forming a gate insulating layer, a semiconductor layer, an etch-stop layer, and a second metal layer;
S20: patterning the second metal layer, the etch-stop layer, and the semiconductor layer with a second mask process to form a source, a drain, and an amorphous silicon island, wherein an edge of the amorphous silicon island is aligned with an edge of the source, an edge of the drain, and an edge of the etch-stop layer;
S30: forming a passivation layer on the gate insulating layer, the source, and the drain, and patterning the passivation layer with a third mask process to form a through-hole; and
S40: patterning a pixel electrode on the passivation layer with a fourth mask process, wherein the pixel electrode is connected to the drain by the through-hole.

11. The manufacturing method of the TFT array substrate according to claim 10, wherein the step S20 further comprises the steps of:
S201: coating a photoresist material on the second metal layer;
S202: exposing and developing the photoresist material with the second mask to form a first photoresist layer;
S203: etching and removing the second metal layer and the etch-stop layer not covered by the first photoresist layer;
S204: ashing the first photoresist layer to form a second photoresist layer, wherein the second photoresist layer corresponds to the source and the drain;
S205: etching the second metal layer to form the source and the drain;
S206: striping the second photoresist layer; and
S207: etching and removing the semiconductor layer not covered by the etch-stop layer, the source, and the drain.

12. The manufacturing method of the TFT array substrate according to claim 11, wherein the semiconductor layer comprises an amorphous silicon layer and a N+ amorphous silicon layer; and
the step S207 further comprises etching and removing the N+ amorphous silicon layer of a channel region to expose the amorphous silicon layer.

13. The manufacturing method of the TFT array substrate according to claim 12, wherein the step S207 further comprises the steps of:
S2071: removing the semiconductor layer outside the etch-stop layer by a dry etching process using the etch-stop layer as a mask;
S2072: removing the etch-stop layer of the channel region by the dry etching process using the source and the drain as a mask; and
S2073: removing the N+ amorphous silicon layer of the channel region to expose the amorphous silicon layer by the dry etching process using the etch-stop layer as a mask.

14. The manufacturing method of the TFT array substrate according to claim 13, wherein a thickness of removing the N+ amorphous silicon layer of the channel region ranges from 100 to 500 angstroms (Å).

15. The manufacturing method of the TFT array substrate according to claim 13, wherein the step S2071, the step S2072, and the step S2073 use a same dry etching process.

16. The manufacturing method of the TFT array substrate according to claim 11, wherein the step S203 uses a wet etching process, and the step S205 uses the wet etching process.

17. The manufacturing method of the TFT array substrate according to claim 10, wherein the second mask comprises a halftone mask.

18. A thin-film transistor (TFT) array substrate, comprising:
a base substrate;
a gate disposed on the base substrate;
a gate insulating layer covering the gate and the base substrate;
an amorphous silicon island disposed on the gate insulating layer;
an etch-stop layer disposed on the amorphous silicon island;
a source and a drain disposed on the etch-stop layer, and a channel region formed between the source and the drain;
a passivation layer disposed on the gate insulating layer, the source, and the drain, and a through-hole disposed on the passivation layer; and
a pixel electrode disposed on the passivation layer, wherein the pixel electrode is connected to the drain by the through-hole;
wherein an edge of the amorphous silicon island is aligned with an edge of the source, an edge of the drain, and an edge of the etch-stop layer.

19. The TFT array substrate according to claim 18, wherein the amorphous silicon island comprises an amorphous silicon layer and a N+ amorphous silicon layer, the N+ amorphous silicon layer corresponds to the source and the drain, and the amorphous silicon layer corresponds to the source, the drain, and the channel region.
